(19) United States
(12) Patent Application Publication
(10) Pub. No.: US 2005/0213363 A1
(43) Pub. Date: Sep. 29, 2005

(54) Non-volatile memory device and inspection method for non-volatile memory device

(75) Inventor: Hirofumi Oga, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/086,588

(22) Filed: Mar. 23, 2005

(30) Foreign Application Priority Data
Mar. 25, 2004 (JP) 2004-089325

(51) Int. Cl. G11C 11/22

(52) U.S. Cl. 365/145

(57) ABSTRACT

In a disturb test of a selected bit line selected from the plurality of bit lines, the first dummy cell corresponding to the selected bit line is selected, data is written by the constant current flowing in the first dummy cell, and a write bit line voltage is simulated which is the voltage generated in the selected bit line when data is written to the memory cell.

### BACKGROUND OF THE INVENTION

1. Field of the Invention

The present invention relates to a non-volatile memory device and an inspection method for a non-volatile memory device.

2. Description of the Related Art

Flash memories and EEPROMs, (hereafter, simply called “memory cells”) are known as non-volatile memory devices. Data stored in the non-volatile memory is not deleted even if the power supply is turned off, provided that it is not erased or overwritten. A “disturb test” is carried out on memory cells in manufacturing steps. In the disturb test, data is written to a certain memory cell, and it is investigated whether or not data is written erroneously to the plurality of other memory cells that are arranged on the same bit line as this memory cell.

The disturb test is now described in detail. FIG. 1 is a circuit diagram partly showing the structure of a conventional non-volatile memory device. This non-volatile memory device comprises a current supply circuit 106, a current supply circuit 107 (including a switch 124), a switch 121, an external voltage terminal 122, a memory cell 115, a plurality of bit lines 117 (although only one is illustrated in the drawing), a plurality of word lines 118 (although only one is illustrated in the drawing), and a plurality of source lines 119 (although only one is illustrated in the drawing).

The bit lines 117 extend in the Y direction (first direction) The word lines 118 extend in the X direction (second direction) which is substantially perpendicular to the Y direction (first direction).

Memory cells 115 are disposed respectively at the positions where the plurality of bit lines 117 and the plurality of word lines 118 intersect with each other. In the memory cells 115, data is written by means of channel hot electrons. Channel hot electrons are generated when a predetermined constant current flows between the source and drain of memory cell 115. The non-volatile memory device illustrated in FIG. 1 is a split gate type non-volatile memory device. The control gate of this memory is connected to the word line 118, the source, to the source line 119, and the drain, to the bit line 117.

The current supply circuit 106 is able to supply a constant current, which is substantially uniform, to the memory cell 115 and its corresponding bit line 117. The external voltage terminal 122 applies a predetermined voltage to the bit line 117, via the switch 121. The current supply circuit 107 supplies a current to the bit line 117, via the switch 124.

The operation of writing data to this memory cell 115 is described below.

Firstly, a selected bit line 117s, a selected word line 118s and a selected source line 119s are selected respectively from the plurality of bit lines 117, the plurality of word lines 118 and the plurality of source lines. A selected cell 115s is selected from the plurality of memory cells, by means of the selected bit line 117s and the selected word line 118s. Next, a voltage VSW (source voltage) is applied to the selected source line 119s, a voltage VWW (gate voltage) is applied to the selected word line 118s. The current supply circuit 106 supplies a predetermined constant current from the selected source line 119s to the selected bit line 117s via the source of the selected cell 115s and the drain of the selected cell. In this case, the voltage VBW of the selected bit line (namely, the drain voltage), is VWW−Vth, where Vth is the threshold voltage of the selected memory cell 115s. When the constant current flows in the selected memory cell 115s, channel hot electrons are generated. Data is written to the memory cell 115s by injecting these channel hot electrons to the floating gate of the cell 115s.

A disturb test for this memory cell 115 is performed as follows.

Firstly, all of the plurality of bit lines 117 are selected as selected bit lines 117s (in FIG. 1, only one bit line 117 is depicted). It is also possible for only one bit line 117 to be selected. Thereupon, the switch 121 is turned on and a predetermined external voltage is applied to the selected bitline 117s from the external voltage terminal 122. The predetermined voltage is the voltage which simulates the voltage VBW=VWW−Vth generated in the selected bit line 117s during the aforementioned data write operation, and this voltage is determined previously by experimentation or simulation. By applying this predetermined voltage to the selected bit line 117s, it is possible to establish circumstances exactly like those existing in the selected bit line 117s and the memory cells 115 arranged on that bit line when data is written to a certain selected cell 115s. Thereupon, data is read out from the memory cells 115 arranged on the selected bit line 117s, and it is investigated whether or not a write disturbance has occurred.

The data is read out from the memory cell 115 as described below.

Firstly, a selected bit line 117s and a selected word line 118s are selected respectively from the plurality of bit lines 117 and the plurality of word lines 118. The plurality of source lines 119 are fixed to 0V and are not selected. A selected cell 115s is selected from the plurality of memory cells on the basis of the selected bit line 117s and the selected word line 118s. Next, a voltage VWR (gate voltage) is applied to the selected word line 118, and a voltage VBR (drain voltage) is applied to the selected bit line 117s. A sense amplifier (not illustrated) senses the current that flows in the path from the selected bit line 117s, to the drain of the selected cell 115s, the source of the selected cell 115s, and the corresponding source line 119s (0V). Since the current varies depending on the electric charge (stored data) accumulated in the floating gate, then it is therefore possible to read out the data.

When a write operation is performed in the memory cell 115 described above, if the threshold voltage Vth is small, then the drain voltage of the memory cell 115 (=voltage of bit line 117, VBW=VWW−Vth) becomes high. In this case, the difference between the source voltage of the memory cell 115 (=voltage of source line 119, VSR=fixed value) and the drain voltage is small, and it becomes more difficult for channel hot electrons to be generated. Consequently, it becomes difficult to write the data. In other words, if the threshold voltage Vth is reduced by a suitable amount, then erroneous data writing becomes less liable to occur, but if it is reduced too far, then normal writing also becomes difficult.

On the other hand, if the threshold voltage Vth is high, then the drain voltage of the memory cell 115 becomes lower. In this case, the difference between the source voltage and the drain voltage of the memory cell 115 increases and it therefore becomes easier for channel hot electrons to be generated. Consequently, data can be written more readily. In other words, if the threshold voltage Vth is increased, then erroneous data writing becomes more liable to occur, but if it is increased by a suitable amount, then normal writing becomes easier.

Therefore, memory cells 115 are designed and manufactured in such a manner that the threshold voltage Vth has a value at which erroneous data writing becomes less liable to occur, while normal writing becomes easier to perform. However, due to the difference in the manufacturing situation of memory cells 115, the value of the threshold voltage Vth varies. Therefore, the voltage of the bit line, VBW=VWMW−Vth varies.

In view of these circumstances, when the aforementioned disturb test is carried out, since the voltage of the bit line 117 is simulated at a previously established external voltage, the voltage generated in the selected bit line 117s by an actual write operation, namely, VBW=VWMW−Vth, is not necessarily simulated accurately. As described above, erroneous data writing may become more or less liable to occur in the memory cell 115, depending on the voltage in the bit line VBW. In other words, if the external voltage is low and erroneous writing becomes more liable to occur, then memory cells which should in principle be passed by the disturb test will end up being failed. Conversely, if the external voltage is high and erroneous writing become less liable to occur, then memory cells which should be failed will end up being passed.

Technology is required which enables the voltage in a selected bit line during an actual write operation to be simulated accurately in a disturb test. Technology is also required which enables the voltage during an actual write operation to be simulated accurately in a disturb test, without involving major design modifications or significant increase in costs. Technology is also required which improves the reliability of evaluation in a disturb test.

Related technology for a non-volatile memory device is disclosed in Japanese Unexamined Patent Application Publication No. 2-310900. This non-volatile memory device comprises a memory array and a dummy word line. The memory array comprises non-volatile semiconductor memory cells each having a control gate and a floating gate, arranged in a matrix configuration at the intersections between word lines and data lines. The dummy word line is formed by providing non-volatile semiconductor memory cell similar to the foregoing at the intersection points with the data lines. In the data line disturb test mode, a write operation is carried out with respect to the non-volatile semiconductor memory cells provided on the dummy word line.

These non-volatile semiconductor memory cells are driven by applying a predetermined fixed voltage to their respective terminals. In the disturb test, a high voltage is applied to the data line (bit line) corresponding to the dummy cell, the word line corresponding to the dummy cell is selected, and a write operation is performed. The stated object of this reference is to improve the reliability of the non-volatile semiconductor memory cells, without damaging the memory cells during a disturb test.

In other words, the voltage applied to the respective terminals of the non-volatile semiconductor memory cells is uniform, and they are not necessarily driven at a constant current. Furthermore, in the disturb test, a high voltage is applied and there is no particular requirement to apply a voltage within a predetermined range. Furthermore, the question of the reliability of the disturb test is not addressed.

Related technology for a non-volatile memory device is disclosed in Japanese Unexamined Patent Application Publication No. 2-108300. This non-volatile memory device comprises a memory array, a switch circuit, an X decoder circuit, and a dummy circuit. Here, the memory array comprises non-volatile semiconductor memory cells, each having a control gate and a floating gate, arranged in a matrix configuration. A switch circuit supplies a high-level write voltage to a plurality of data lines, which respectively couple together the drains of non-volatile semiconductor memory cells, in accordance with a signal supplied from an external terminal or a combination of signals. An X decoder circuit has a function whereby, during the operating mode in which the high-level write voltage is supplied to the plurality of data lines by the aforementioned switch circuit, the word line is unselected. A dummy circuit creates a high-level voltage which is applied to the plurality of data lines by a dummy non-volatile memory cells that is set to a write state during the aforementioned operating mode.

### SUMMARY OF THE INVENTION

A non-volatile memory device comprises a plurality of bit lines extending in a first direction, a plurality of word lines extending in a second direction substantially perpendicular to the first direction, a first dummy word line extending in the second direction, a plurality of memory cells, being non-volatile semiconductor memory cells to which data is written by a constant current, provided respectively so as to correspond to the positions of the intersections between the plurality of bit lines and the plurality of word lines, a plurality of first dummy cells, being non-volatile semiconductor memory cells to which data is written by the constant current, provided respectively so as to correspond to the positions of the intersections between the plurality of bit lines and the first dummy word line and a current source capable of supplying the constant current to the memory cell or the first dummy cell and the corresponding bit line.

In a disturb test of a selected bit line selected from the plurality of bit lines, the first dummy cell corresponding to the selected bit line is selected, data is written by the constant current flowing in the first dummy cell, and a write bit line voltage is simulated which is the voltage generated in the selected bit line when data is written to the memory cell.

### BRIEF DESCRIPTION OF THE DRAWINGS

The above and other objects, advantages and features of the present invention will be more apparent from the following description taken in conjunction with the accompanying drawings, in which:

FIG. 1 is a circuit diagram showing a portion of the composition of a conventional non-volatile memory device;

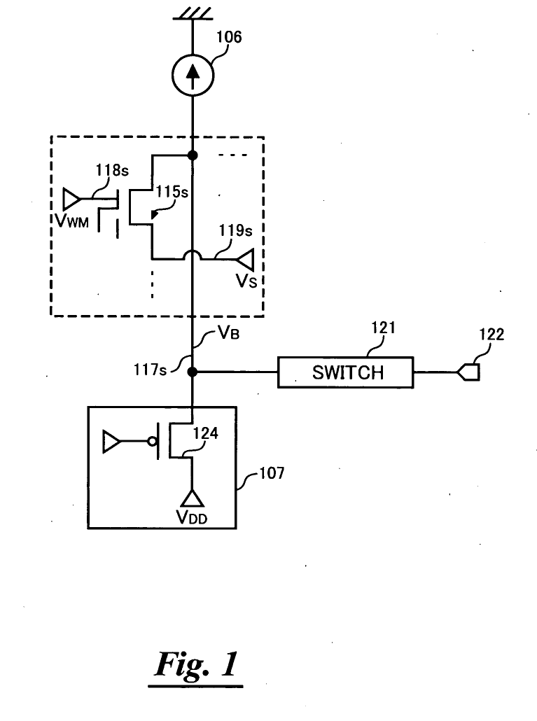

FIG. 2 is a circuit block diagram showing the composition of a first embodiment of the non-volatile memory device according to the present invention,

FIG. 3 is a flow diagram showing a first embodiment of an inspection method for a non-volatile memory device according to the present invention;

FIG. 4 is a circuit block diagram showing the composition of a second embodiment of a non-volatile memory device according to the present invention;

FIG. 5 is a flow diagram showing a second embodiment of an inspection method for a non-volatile memory device according to the present invention;

FIG. 6 is a flow diagram showing a method for testing the reliability of a terminal;

FIG. 7 is a circuit block diagram showing a further composition of a first embodiment of a non-volatile memory device according to the present invention; and

FIG. 8 is a circuit block diagram showing a portion of a further composition of a second embodiment of a non-volatile memory device according to the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

A first embodiment of a non-volatile memory device and an inspection method for a non-volatile memory device according to the present invention is now described with reference to the accompanying drawings.

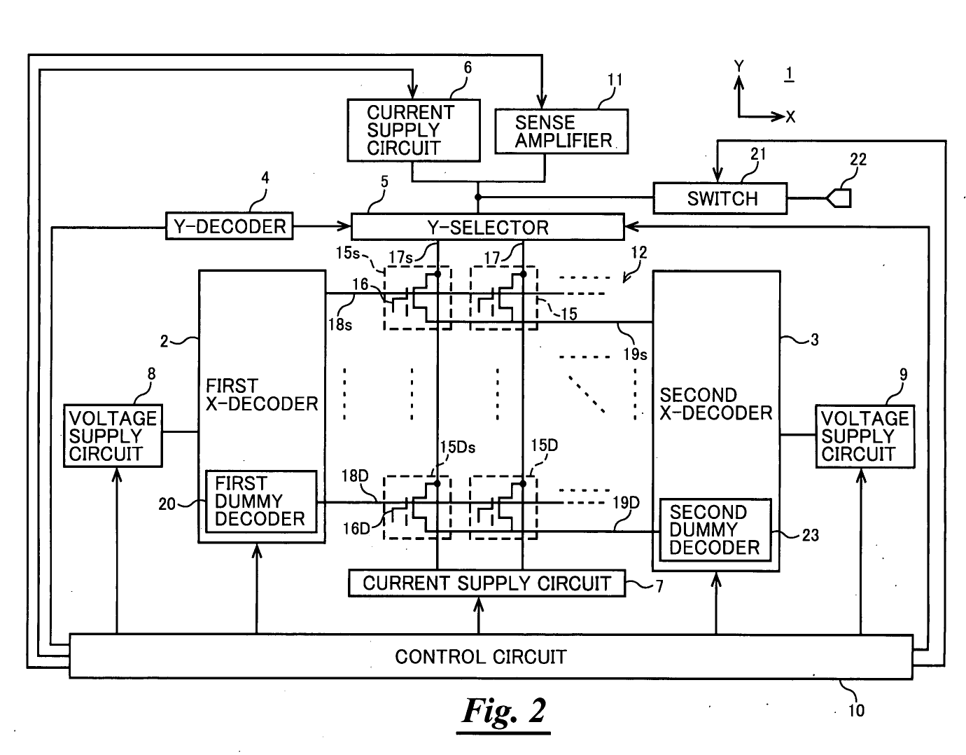

FIG. 2 is a circuit block diagram showing the structure of a first embodiment of a non-volatile memory device according to the present invention. The non-volatile memory device 1 comprises a first X decoder 2, a first dummy decoder 20, a second X decoder 3, a second dummy decoder 23, a Y decoder 4, a Y selector 5, a plurality of bit lines 17 (in the diagram, only two are depicted), a plurality of word lines 18 (in the diagram, only one is depicted), a plurality of source lines 19 (in the diagram, only one is depicted), a dummy word line 18D, a dummy source line 19D, a plurality of memory cells 15 (in the diagram, only two are depicted), a plurality of dummy cells 15D (in the diagram, only two are depicted), a current supply circuit 6, a current supply circuit 7, a voltage supply circuit 8, a voltage supply circuit 9, a control circuit 10, a sense amplifier 11, a switch 21, and an external voltage terminal 22. The memory array 12 comprises a plurality of memory cells 15 and a plurality of dummy cells 15D.

The bit lines 17 extend in the Y (first) direction. One end of each bit line is connected to the Y selector 5, and the other end thereof is connected respectively to the current supply circuit 7. The word lines 18 extend in the X direction (second direction), which is substantially perpendicular to the Y direction (first direction). Here, “substantially” means within a certain range of error (the same applies below). One terminal of each word line is connected to the first X decoder 2. The source lines 19 extend in the X direction. One end of each source line is connected to the second X decoder 3.

The dummy word line 18D extends in the X direction. One end of the dummy word line 18D is connected to the first dummy decoder 20. The first dummy decoder 10 is included in the first X decoder 2. The dummy source line 19D extends in the X direction. One end of the dummy source line 19D is connected to a second dummy decoder 23. The second dummy decoder 23 is included in the second X decoder 3.

Memory cells 15 are provided respectively at the positions of the intersections between the plurality of bit lines 17 and the plurality of word lines 18. These memory cells are non-volatile semiconductor memory cells. Data is written to the memory cells by a predetermined constant current flowing between the drain and the source. When the predetermined constant current flows, the channel hot electrons are generated and injected to a floating gate. A split gate type non-volatile memory is depicted as one example of a non-volatile semiconductor memory cell. In each cell, the control gate is connected to a word line 18, the source is connected to a source line 19 and the drain is connected to a bit line 17.

Dummy cells 15D are provided respectively at the positions of the intersections between the plurality of bit lines 17 and the dummy word line 18D. The structure and operation of these dummy cells 15D are the same as those of the memory cells 15, and they are manufactured by the same process as the memory cells 15. Therefore, their characteristics are the same as those of the other memory cells 15, including any manufacturing fluctuations. The control gate, source and drain of the dummy cells 15D are connected respectively to the dummy word line 18D, the dummy source line 19D and the bit line 17.

The first X decoder 2 selects (activates) one word line 18 to be a selected word line 18s, among the plurality of word lines 18, based on a control signal from the control circuit 10. The second X decoder 3 selects (activates) one source line 19 to be a selected source line 19s, among the plurality of source lines 19, based on a control signal from the control circuit 10. Alternatively, it selects all of the plurality of source lines 19. The Y decoder 4 decodes the address signal included in the control signal received from the control circuit 10, and outputs this address signal to the Y selector 5. The Y selector 5 selects (activates) one bit line 17 to be a selected bit line 17s, among the plurality of bit lines 17, based on the control signal from the control circuit 10 and the address signal from the Y decoder 4. Alternatively, it selects all of the plurality of bit lines 17.

Based on the selected bit line 17s and the selected word line 18s, (and the selected source line 19s), one memory cell 15 is selected as a selected cell 15s among the plurality of memory cells 15. If all of the plurality of bit lines 17 are selected, then the memory cells 15 on the selected word line 18s are selected as the selected cells 15s.

The first dummy decoder 20 selects (activates) the dummy word line 18D based on a control signal from the control circuit 10. The second dummy decoder 24 selects (activates) the dummy source line 19D based on a control signal from the control circuit 10.

One dummy cell 15D is selected as a selected dummy cell 15Ds from the plurality of dummy cells 15D, on the basis of the selected bit line 17s and the dummy word line 18D (and the dummy source line 19D). If all of the plurality of bit lines 17 have been selected, then the dummy cells 15D on the dummy word line 18D are selected as selected dummy cells 15Ds.

The current supply circuit 6 is able to supply a constant current which is substantially uniform, via the Y selector 5, to a path from the bit line 17, to the memory cell 15, to the source line 19, and from the bit line 17, to the dummy cell 15D, to the dummy source line 19D, on the basis of the control signal from the control circuit 10. The current supply circuit 7 is able to supply a constant current to the bit line 17 on the basis of the control signal from the control circuit 10.

The voltage supply circuit 8 is able to apply a predetermined voltage respectively to the word line 18, via the first X decoder 2, and to the dummy word line 18D, via the first dummy decoder 20, on the basis of the control signal from the control circuit 10. The voltage supply circuit 9 is able to apply a predetermined voltage respectively to the source line 19, via the second X decoder 3, and to the dummy source line 19D, via the second dummy decoder 23, on the basis of the control signal from the control circuit 10.

During a read out operation, the sense amplifier 11 reads out the data stored in the selected cell 15s and the selected dummy cell 15Ds, based on the current flowing in the selected cell 15s and the selected dummy cell 15Ds.

The external voltage terminal 22 is a terminal for applying an external voltage to the bit line 17. The external voltage terminal 22 is connected to the internal circuit via a switch 21.

The control circuit 10 controls the operations of the first X decoder 2, the first dummy decoder 20, the second X decoder 3, the second dummy decoder 23, the Y decoder 4, the Y selector 5, the current supply circuit 6, the current supply circuit 7, the voltage supply circuit 8, the voltage supply circuit 9, the sense amplifier 11, and the switch 21. For example, a CPU can be used as a control circuit 10. Under the control of the control circuit 10, a write operation, read-out operation, erase operation and disturb test are carried out. For example, the control circuit 10 controls these operations based on a prescribed program. The program may be stored in a storage device, such as a ROM (not illustrated).

A write operation and read-out operation performed in the non-volatile memory device 1 will be described.

Referring to FIG. 2, a data write operation to a memory cell 15 is carried out as described below.

Firstly, a selected word line 18s is selected from the plurality of word lines 18 by the first X decoder 2. A selected source line 19s is selected from the plurality of source lines by the second X decoder 3. A selected bit line 17s is selected from the plurality of bit lines 17 by the Y selector 5. A selected cell 15s is selected from the plurality of memory cells in accordance with the selected bit line 17s and the selected word line 18s.

Next, the voltage supply circuit 9 applies a voltage VSW (source voltage, e.g. 7.5V) to the selected source line 19s. The voltage supply circuit 8 applies a voltage VWW (gate voltage, e.g. 1.5V) to the selected word line 18s.

A predetermined constant current flows from the selected source line 19s to the selected bit line 17s via the source and the drain of the selected cell 15s by the current supply circuit 6.

In this case, the voltage VBW (drain voltage) of the selected bit line is VWW−Vth. Here, Vth is the threshold voltage of the selected cell 15s. In this case, data is written to the selected cell 15s by injecting channel hot electrons into the floating gate. The channel hot electrons are generated by the constant current flowing in the selected cell 15s.

In the case of the example voltages given above, the unselected source lines 19 is a floating state, the unselected word lines 18 are set to 0V, and the unselected bit lines 17 are set to 3.2V.

A data read-out operation from a memory cell 15 is now described with reference to FIG. 2.

Firstly, a selected word line 18s is selected from the plurality of word lines 18 by the first X decoder 2. A selected bit line 17s is selected from the plurality of bit lines 17 by the Y selector 5. No source line is selected, and all of the plurality source lines are set to 0V. A selected cell 15s is selected from the plurality of memory cells, in accordance with the selected bit line 17s and the selected word line 18s.

Next, the voltage supply circuit 8 applies a voltage VWR (gate voltage, e.g. 2.5V) to the selected word line 18s. The selected bit line 17s is set to a voltage VBR (drain voltage, e.g. 0.5V) The sense amplifier 11 senses the current flowing from the selected bit line 17s to selected source line 19s, via the drain and the source of the selected cell 15s. In this case, since the amount of the current varies depending on the electric charge (stored data) that has been accumulated in the floating gate of the cell, then the stored data can be read out.

In the case of the example voltages given above, the unselected word lines 18 and bit lines 17 are set respectively to 0V.

An operation of erasing data in the memory cell 15 is now described with reference to FIG. 2.

Firstly, a selected word line 18s is selected from the plurality of word lines 18 by the first X decoder 2. The plurality of source lines 19 and the plurality of bit lines 17 are all fixed to 0V and are not selected. All of the memory cells 15 on the selected word line 18s are selected as selected cells 15s.

Thereupon, the voltage supply circuit 8 applies a voltage VWR (gate voltage, e.g. 12V) to the selected word line 18s. Consequently, the electrons are extracted from the floating gate, by a Fowler-Nordheim (FN) tunneling effect, and hence the data can be erased.

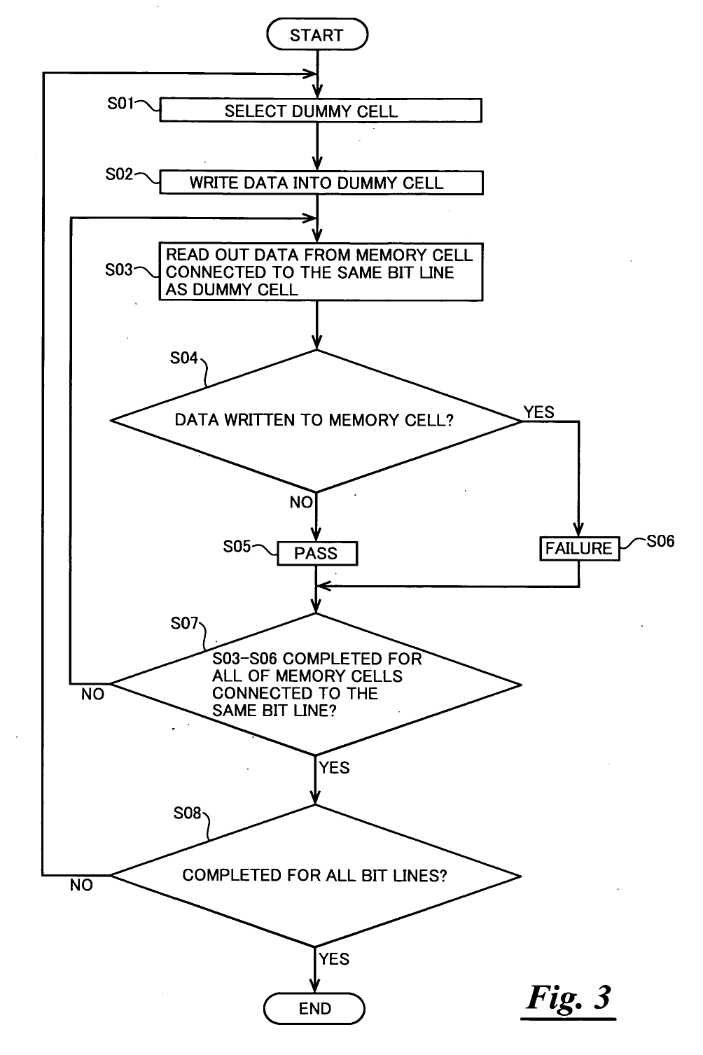

Next, a disturb test is described with reference to the drawings. FIG. 3 is a flow chart showing a first embodiment of an inspection method for a non-volatile memory device according to the present invention.

(1) Step S01

A dummy word line 18D is selected by the first dummy decoder 20. A dummy source line 19D is selected by the second dummy decoder 23. A selected bitline 17s is selected from the plurality of bit lines 17 by the Y selector 5. A selected dummy cell 15Ds is selected from the plurality of dummy cells 15D, in accordance with the selected bit line 17s and the dummy word line 18D.

(2) Step S02

The voltage supply circuit 9 applies a voltage VSDW (source voltage, e.g. 7.5V) to the dummy source line 19D. The voltage supply circuit 8 applies a voltage VWDW (gate voltage, e.g. 1.5V) to the dummy word line 18D. The current supply circuit 6 causes a predetermined constant current to flow from the dummy source line 19D to the selected bit line 17Ds, via the source and the drain of the selected dummy cell 15Ds. In this case, the voltage VBDW (drain voltage) of the selected bit line 17s is VWDW−Vth. Here, Vth is the threshold voltage of the selected dummy cell 15Ds. In this case, data is written to the selected dummy cell 15Ds by injecting the channel hot electrons into the floating gate of the cell. The channel hot electrons are generated by the constant current flowing through the selected dummy cell 15Ds.

In the case of the example voltages given above, the unselected source line 19, word line 18 and bit line 17 are respectively set to 0V, 0V and 3.2V.

(3) Step S03

A selected word line 18s is selected from the plurality of word lines 18 by the first X decoder 2. The plurality of source lines are all fixed to 0V and are not selected. The selected bit line 17s is already selected in step S01. A selected cell 15s is selected from the plurality of memory cells, by means of the selected bit line 17s and the selected word line 18s. Data is read out from the selected cell 15s by means of the aforementioned read out operation.

(4) Step S04

The control circuit 10 judges whether or not data has been written to the selected cell 15s, on the basis of the read out data. In other words, it judges whether or not data has been written to another memory cell 15 located on the same selected bit line 17s as the selected dummy cell 15Ds, by the writing of data to the selected dummy cell 15Ds in step S02 (namely, whether or not a write disturbance has occurred).

(5) Step S05

If no data has been written to the selected cell 15s, (Step S04: No), then that selected cell 15s is taken to have passed the disturb test, and a signal indicating a pass is output by the control circuit 10.

(6) Step S06

If data has been written to the selected cell 15s (Step S04: Yes), then that selected cell 15s is taken not to have passed the disturb test, and the control circuit 10 outputs a signal indicating a failure.

(7) Step S07

The control circuit 10 judges whether or not the inspection in steps S03-S06 has been completed for all of the memory cells 15 on the selected bit line 17s selected at step S01. If it has not been completed (Step S07: No), then the procedure returns to step S03 and inspection is continued for the remaining memory cells 15.

(8) Step S08

The control circuit 10 judges whether or not the inspection in steps S01-S07 has been completed for all of the bit lines 17 relating to the memory cell array 12 under inspection. If inspection has been completed (Step S08: No), then the procedure returns to step S01 and inspection is continued for the memory cells 15 on the remaining bit lines 17.

Disturb testing is carried out by means of the steps S01-S08 described above.

In the aforementioned disturb test, the voltage generated during a write operation to the dummy cell 15D (of the same characteristics as the memory cell) is used as the voltage applied to the bit line 17 in the disturb test. In other words, the voltage generated in the selected bit line 17s during an actual write operation is simulated. Therefore, it is possible to prevent situations which occur when an externally applied voltage is used, such as memory cells which in principle ought to be passed by the disturb test being failed, or conversely, memory cells which in principle ought to be failed being passed, due to inappropriate setting of the voltage value applied to the bit line 17.

The present invention is able to simulate accurately the voltage generated by an actual write operation, during a disturb test, without requiring major design modifications or significant increase in costs. Therefore, the reliability of evaluation based on a disturb test can be improved.

In FIG. 2, the dummy cells 15D are provided separately, but it is also possible to use one row of the memory cells 15 in the memory cell array 12 as the dummy cells. In this case, the procedure illustrated in FIG. 3 is carried out by taking the memory cell 15 at a prescribed address as a dummy cell. Furthermore, in this case, it is possible to implement the inspection method for a non-volatile memory device according to the present invention without providing a special structure.

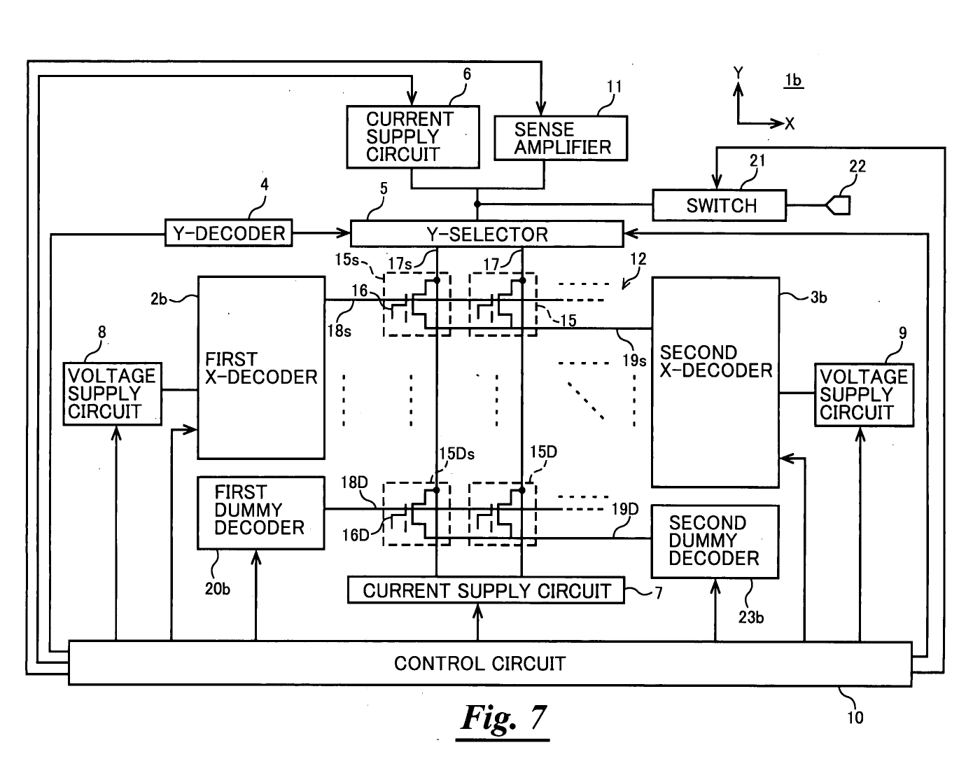

The first dummy decoder 20 can be provided externally to the first X decoder 2, and the second X decoder 3 can be provided externally to the second dummy decoder 23, respectively. This configuration is illustrated in FIG. 7. FIG. 7 is a circuit block diagram showing a further configuration of a first embodiment of the non-volatile memory device according to the present invention. In FIG. 7, the first dummy decoder 20 is provided externally to the first X decoder 2 and the second X decoder 3 is provided externally to the second dummy decoder 23. This non-volatile memory device 1b has the same structure and operation as that illustrated in FIG. 2 except for the dummy decoders, and hence further description thereof is omitted here. In this case, similar beneficial effects to those of the configuration illustrated in FIG. 2 can be obtained.

### Second Embodiment

A second embodiment of a non-volatile memory device and an inspection method for a non-volatile memory device according to the present invention is now described with reference to the accompanying drawings.

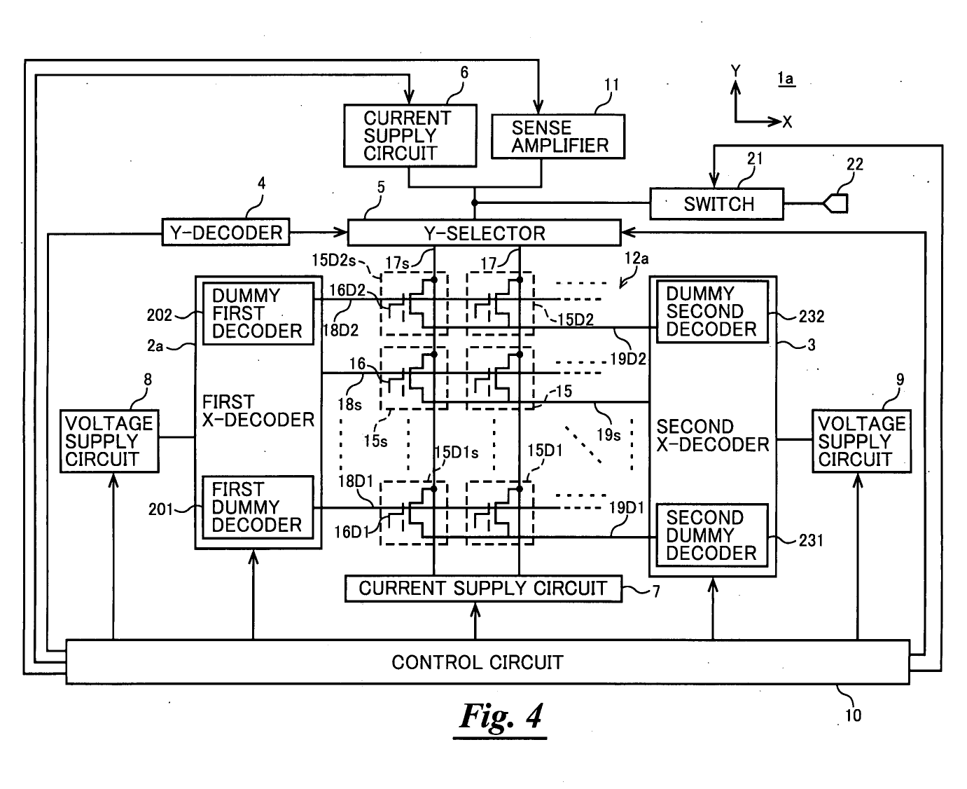

FIG. 4 is a circuit block diagram showing the structure of a second embodiment of the non-volatile memory device according to the present invention. This non-volatile memory device 1a differs from that of the first embodiment in that new elements as follows are added. A first dummy decoder 20-2 is provided in addition to a first dummy decoder 20-1 inside the first X decoder 2a. A second dummy decoder 23-2 is provided in addition to a second dummy decoder 23-1 inside the second X decoder 3a. A dummy word line 18D2 is provided in addition to a dummy word line 18D1. A dummy source line 19D2 is provided in addition to a dummy source line 19D1. A plurality of second dummy cells 15D2 (two are depicted in the drawings) are provided in addition to a plurality of first dummy cells 15D1 (two are depicted in the drawings).

The dummy word line 18D1 extends in the X direction. One end of this line is connected to the first dummy decoder 20-1 included in the first X decoder 2a. The dummy source line 19D1 extends in the X direction. One end of this line is connected to a second dummy decoder 23-1 included in the second X decoder 3a. Similarly, the dummy word line 18D2 extends in the X-direction. One end of this line is connected to the first dummy decoder 20-2 included in the first X decoder 2a. The dummy source line 19D2 extends in the X direction. One end of this line is connected to a second dummy decoder 23-2 included in the second X decoder 3a.

First dummy cells 15D1 are provided respectively at the positions of the intersections between the plurality of bit lines 17 and the dummy word line 18D1. These dummy cells 15D1 have the same structure and operation as the memory cells 15, and they are manufactured by the same process as the memory cells 15. Therefore, their characteristics are the same as those of the other memory cells 15, including any manufacturing fluctuations. The control gate, source and drain of the first dummy cells 15D1 are connected respectively to the dummy word line 18D1, the dummy source line 19D1 and the bit line 17. Similarly, second dummy cells 15D2 are provided respectively at the positions of the intersections between the plurality of bit lines 17 and the dummy word line 18D2. These dummy cells 15D2 have the same structure and operation as the memory cells 15, and they are manufactured by the same process as the memory cells 15. Therefore, their characteristics are the same as those of the other memory cells 15, including any manufacturing fluctuations. The control gate, source and drain of the first dummy cells 15D2 are connected respectively to the dummy word line 18D2, the dummy source line 19D2 and the bit line 17.

Desirably, the first dummy cell 15D1 and the second dummy cell 15D2 are provided in separate rows in the same memory cell array 12a. This is because, if there is a problem with the operation of one dummy cell, then this will not affect the separate row. Furthermore, in the present embodiment, two dummy cell rows are provided, but it is also possible to provide further rows in order to increase reliability.

The remaining structure is the same as that of the first embodiment, and description thereof is omitted here.

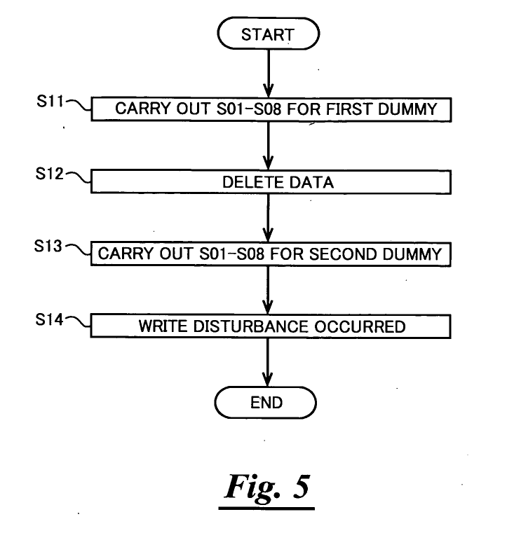

Next, a disturb test is described with reference to the drawings. FIG. 5 is a flow chart showing a second embodiment of an inspection method for a non-volatile memory device according to the present invention.

(1) Step S11

The dummy word line 18D1 is selected by the first dummy decoder 20-1. The steps S01-S08 of the first embodiment are implemented using the plurality of first dummy cells 15D1 on this dummy word line 18D1. The result is stored in (output to) a storage section (not illustrated).

(2) Step S12

The data in the memory cells 15 of the memory array 12a is erased by the aforementioned erasure operation.

(3) Step S13

The dummy word line 18D2 is selected by the second dummy decoder 20-2. The steps S01-S08 of the first embodiment are carried out using the plurality of second dummy cells 15D2 on this dummy word line 18D2. The result is stored in (output to) a storage section (not illustrated).

(4) Step S14

The control circuit 10 compares the result of step S11 with the result of step S13, and judges whether or not a write disturbance has occurred. It judges that a write disturbance has occurred if a write disturbance is indicated in at least one of step S11 and/or step S13.

A disturb test is performed by means of steps S11-S14 described above.

It is also possible to obtain similar beneficial effects to those of the first embodiment, by means of the aforementioned disturb test. In addition, since two rows of dummy cells are provided, then it is possible further to improve the reliability of evaluation based on the disturb test.

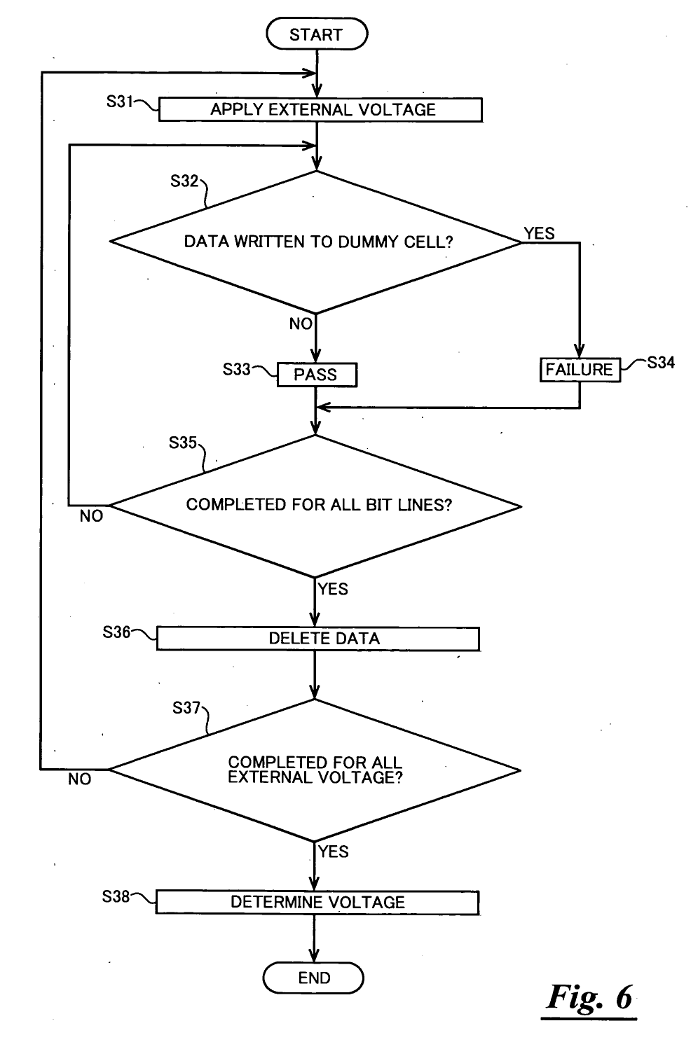

It is also possible to adopt the following method in respect of the dummy cells 15D (15D1, 15D2). FIG. 6 is a flow diagram showing a method for inspecting the reliability of dummy cells.

(1) Step S31

All of the plurality of bit lines 17 are selected by the first Y decoder 4. The switch 21 is turned on, and a predetermined external voltage is applied to the plurality of bit lines 17s from the external voltage terminal 22. Here, the predetermined voltage is a voltage which simulates the voltage, VBW=VWW−Vth, arising in the selected bit line 17s during the aforementioned data write operation, and the value of this voltage is determined previously through experimentation and simulation. A plurality of predetermined voltages are determined within a prescribed range, to account for design variations.

(2) Step S32

The control circuit 10 performs data read-out from the dummy cells 15D (15D1, 15D2) on the plurality of bit lines 17. The control circuit 10 judges whether or not data has been written to the selected dummy cells 15Ds (15D1s, 15D2s) selected for read out, on the basis of the read out data. More specifically, it judges whether or not data has been written to the selected dummy cells 15Ds (15D1s, 15D2s) by the application of voltage to the plurality of bit lines 17 from the external voltage terminal 22 (in other words, it judges whether or not a write disturbance has occurred).

(3) Step S33

If data has not been written to the selected dummy cells 15Ds (15D1s, 15D2s) (Step S32: No), then the selected dummy cells 15Ds (15D1s, 15D2s) are taken to have passed the disturb test, and the control circuit 10 stores (outputs) a signal indicating a pass.

(4) Step S34

If data has been written to the selected dummy cells 15Ds (15D1s, 15D2s) (Step S32: Yes), then the selected dummy cells 15Ds (15D1s, 15D2s) are taken to have failed the disturb test, and the control circuit 10 stores (outputs) a signal indicating a failure.

(5) Step S35

The control circuit 10 judges whether or not the inspection in the steps S31-S34 has been completed for all of the bit lines 17 under inspection. If inspection has been completed (Step S35 No), then the procedure returns to step S32, and inspection is continued in respect of the selected dummy cells 15D (15D1, 15D2) on the remaining bit lines 17.

(6) Step S36

Since inspection of write disturbances has been completed in respect of all of the dummy cells 15D (15D1, 15D2) at a single prescribed external voltage, the data in the dummy cells 15D (15D1, 15D2) is erased by means of the aforementioned erasure operation.

(7) Step S37

It is judged whether or not the inspection in steps S31-S36 has been completed for a plurality of external voltages. If it has not been completed (step S37: No), then the procedure returns to step S31 and inspection is continued for the remaining external voltages.

By carrying out the inspection in steps S31-S36 at a plurality of external voltages, problems which may occur when inspecting at a single external voltage (as described in relation to the prior art) are eliminated and the dummy cells 15D (15D1, 15D2) can be evaluated accurately.

(8) Step S38

The control circuit 10 determines the circumstances of the respective dummy cells 15D (15D1, 15D2) from the measurement results at all of the external voltages. These circumstances are determined, for example, using the external voltage at which the greatest number of dummy cells 15D (15D1, 15D2) pass the test.

The reliability of the dummy cells is tested by means of the steps S31 to S38 described above.

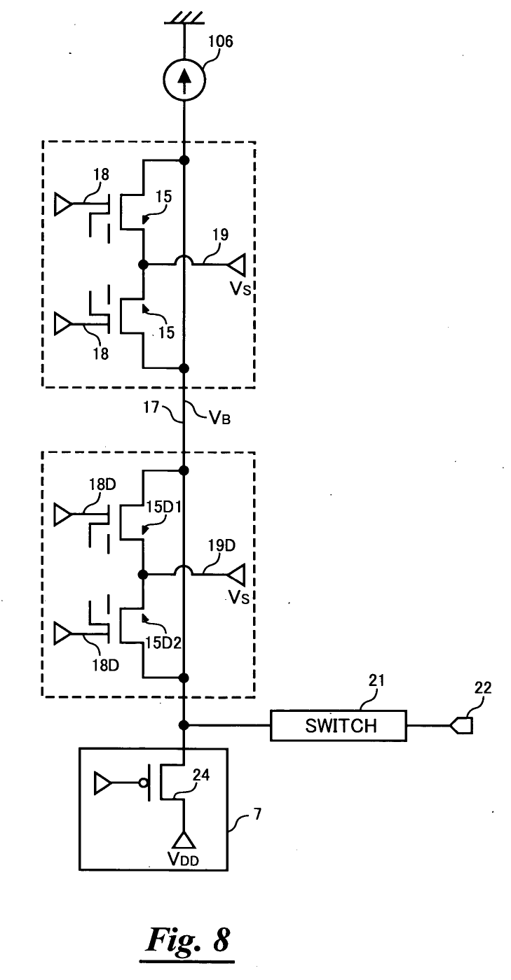

It is also possible to use a structure in which a common source line is adopted for the source line 19 and the dummy source line 19D. FIG. 8 shows a structure of this kind. FIG. 8 is a circuit block diagram showing one portion of a further structure of a second embodiment of the non-volatile memory device according to the present invention. Apart from the fact that a memory cell having an adjacently positioned source line 19 and dummy source line 19D is used, the structure and operation are the same as those illustrated in FIG. 2 and description thereof is omitted. In this case also, similar beneficial effects to those of the structure illustrated in FIG. 2 can be obtained.

It is apparent that the present invention is not limited to the above embodiment, that may be modified and changed without departing from the scope and spirit of the invention.

1. A non-volatile memory device comprising:
a plurality of bit lines extending in a first direction;
a plurality of word lines extending in a second direction substantially perpendicular to the first direction;
a first dummy word line extending in the second direction;
a plurality of memory cells, being non-volatile semiconductor memory cells to which data is written by a constant current, provided respectively so as to correspond to the positions of the intersections between the plurality of bit lines and the plurality of word lines;
a plurality of first dummy cells, being non-volatile semiconductor memory cells to which data is written by the constant current, provided respectively so as to correspond to the positions of the intersections between the plurality of bit lines and the first dummy word line; and
a current source capable of supplying the constant current to the memory cell or the first dummy cell, and the corresponding bit line;
wherein, in a disturb test of a selected bit line selected from the plurality of bit lines, the first dummy cell corresponding to the selected bit line is selected, data is written by the constant current flowing in the first dummy cell, and a write bit line voltage is simulated which is the voltage generated in the selected bit line when data is written to the memory cell.

2. The non-volatile memory device according to claim 1, further comprising a dummy decoder for activating the first dummy word line during the disturb test.

3. The non-volatile memory device according to claim 1, wherein the first dummy word line is one of the plurality of word lines.

4. The non-volatile memory device according to claim 1, comprising:
a second dummy word line extending in the second direction; and
a plurality of second dummy cells, being non-volatile semiconductor memory cells to which data is written by the constant current, provided respectively so as to correspond to the positions of the intersections between the plurality of bit lines and the second dummy word line;
wherein the current source is also able to supply the constant current to the second dummy cell; and
during a disturb test relating to the selected bit line, the second dummy cell corresponding to the selected bit line is selected, data is written by passing the constant current through the second dummy cell, and the write bit line voltage is simulated.

5. The non-volatile memory device according to claim 4, wherein the second dummy word line is one of the plurality of word lines.

6. An inspection method for a non-volatile memory device, the non-volatile memory device comprising:
a plurality of bit lines extending in a first direction;
a plurality of word lines extending in a second direction substantially perpendicular to the first direction;
a first dummy word line extending in the second direction;
a plurality of memory cells, being non-volatile semiconductor memory cells to which data is written by a constant current, provided respectively so as to correspond to the positions of the intersections between the plurality of bit lines and the plurality of word lines;
a plurality of first dummy cells, being non-volatile semiconductor memory cells to which data is written by the constant current, provided respectively so as to correspond to the positions of the intersections between the plurality of bit lines and the first dummy word line; and
a current source capable of supplying the constant current to the memory cell or the first dummy cell, and the corresponding bit line;
and the inspection method comprising:
selecting a first dummy word line;
selecting a selected bit line from the plurality of bit lines;
writing data by supplying the constant current to a selected first dummy cell selected by means of the first dummy word line and the selected bit line, and to the selected bit line; and
judging whether or not data has been written to those memory cells which correspond to the selected bit line;
wherein the voltage in writing data to the selected first dummy cell simulates a write bit line voltage, which is the voltage generated in the selected bit line when data is written to one of the plurality of memory cells corresponding to the selected bit line.

7. The inspection method for a non-volatile memory device according to claim 6, wherein the first dummy word line is one of the plurality of word lines.

8. The inspection method for a non-volatile memory device according to claim 6, wherein the non-volatile memory device further comprises:
a second dummy word line extending in the second direction; and
a plurality of second dummy cells, being non-volatile semiconductor memory cells to which data is written by the constant current, provided respectively so as to correspond to the positions of the intersections between the plurality of bit lines and the second dummy word line; and
wherein the current source also supplies a constant current through the second dummy cells; and
the inspection method further comprises:
selecting a second dummy word line which is different from the first dummy word line;
writing data by supplying the constant current to a selected second dummy cell selected by means of the second dummy word line and the selected bit line, and to the selected bit line; and
judging whether or not data has been written to those memory cells which correspond to the selected bit line; and
the voltage generated in writing data to a selected second dummy cell simulates the write bit line voltage.

9. The inspection method of the non-volatile memory device according to claim 8, wherein the second dummy word line is one of a plurality of word lines.

10. A computer program product, in a computer readable medium, for executing an inspection method for a non-volatile memory device, the non-volatile memory device comprising:
a plurality of bit lines extending in a first direction;
a plurality of word lines extending in a second direction substantially perpendicular to the first direction;
a first dummy word line extending in the second direction;
a plurality of memory cells, being non-volatile semiconductor memory cells to which data is written by a constant current, provided respectively so as to correspond to the positions of the intersections between the plurality of bit lines and the plurality of word lines;
a plurality of first dummy cells, being non-volatile semiconductor memory cells to which data is written by the constant current, provided respectively so as to correspond to the positions of the intersections between the plurality of bit lines and the first dummy word line; and
a current source capable of supplying the constant current to the memory cell or the first dummy cell, and the corresponding bit line;
wherein the program causes a computer to execute an inspection method comprising the steps of:
selecting a first dummy word line;
selecting a selected bit line from the plurality of bit lines;
writing data by supplying the constant current to a selected first dummy cell selected by means of the first dummy word line and the selected bit line, and to the selected bit line; and
judging whether or not data has been written to those memory cells, of the plurality of memory cells, which correspond to the selected bit line; and
the voltage in writing data to the selected first dummy cell simulates a write bit line voltage which is the voltage generated in the selected bit line when data is written to one of the plurality of memory cells corresponding to the selected bit line.

11. The computer program according to claim 10, wherein the first dummy word line is one of the plurality of word lines.

12. The computer program according to claim 10, wherein the non-volatile memory device further comprises:
a second dummy word line extending in the second direction; and
a plurality of second dummy cells, being non-volatile semiconductor memory cells to which data is written by the constant current, provided respectively so as to correspond to the positions of the intersections between the plurality of bit lines and the second dummy word line;
wherein the current source also passes a constant current through the second dummy cells;
the program further comprises the steps of:
selecting a second dummy word line which is different from the first dummy word line;
writing data by passing the constant current to a selected second dummy cell selected by means of the second dummy word line and the selected bit line, and to the selected bit line; and
judging whether or not data has been written to those memory cells of the plurality of memory cells which correspond to the selected bit line; and
the voltage in writing data to the selected second dummy cell simulates the write bit line voltage.

13. The program according to claim 12, wherein the second dummy word line is one of the plurality of word lines
